(19) United States
(12) Patent Application Publication
(10) Pub. No.: US 2007/0233928 A1
(43) Pub. Date: Oct. 4, 2007

(54) Mechanism and apparatus for dynamically providing required resources for a hot-added PCI express endpoint or hierarchy

(76) Inventor: Robert Gough, Cornelius, OR (US)

Correspondence Address: INTEL CORPORATION;c/o INTELLEVATE, LLC, P.O. BOX 52050, MINNEAPOLIS, MN, 55402, US

(21) Appl. No.: 11/395,948

(22) Filed: Mar. 31, 2006

(51) Int. Cl. G06F 13/00; H05K 7/10

(52) U.S. Cl. 710/301; 710/104

(57) ABSTRACT

A method and apparatus is described herein for dynamically allocating resources to root ports. Upon initialization of a system, resources, such as memory space, I/O space, and/or bus numbers are allocated to devices and corresponding windows are assigned to root ports present upstream from those devices. A remaining amount of resources are reserved into a resource pool. When a new device is inserted at runtime, a handler services the insertion notification by assigning an appropriate resource window from the resource pool to the root port upstream from the newly added device. In contrast, upon removal the window of resources are re-assigned back to the resource pool.

### FIELD

This invention relates to the field of interconnects and, in particular, to dynamically providing resources for interconnect devices.

### BACKGROUND

Computer systems have quickly become the center of numerous operations performed in households throughout the world. Previously, a computer was used only for computing operations; however, uses for computers have progressed from this simple model into an electronics hub. A few examples of this progression include using a computer as a media center, a TV, a stereo, and a picture repository. As a result, the number of devices that are connected to a computer continue to increase daily, from internal components, such as audio device, network adapters, and video controllers, to external components such as portable storage devices, cameras, and audio/video equipment.

As a consequence, the interconnect structure to ensure compatibility with all of the aforementioned devices has become increasingly complex. Examples of current interconnects include Peripheral Component Interconnect (PCI), PCI Express (PCI-X) or (PCI-X), Universal Serial Bus (USB), Serial Advanced Technology Attachment (SATA) interconnect, Interconnect Controller Hub (ICH) interconnect, Hublink, IEEE-1394 (Firewire), as well as numerous others.

To provide maximum flexibility in the connection of devices to a computer system, often a system supports removal or addition of a device during operation, which is often referred to as hot plug/swap. Hot plug allows for users to plug in a camera, portable storage device, or other device without having to shutdown the computer and wait for it to reboot. Software tools in operating systems, such as plug-and-play (PnP) managers have been developed to enable a hot swap concept. Therefore, upon removal/addition of a device, a PnP manager is tasked with removing/adding the device from an operating system's perspective.

Typically, upon boot or initialization of a computer system, basic input/output software (BIOS) assigns certain resources, such as I/O space, memory space, and bus numbers to each interconnect device. Specifically, BIOS associates I/O space, memory space, and bus numbers with a specific device in a root port or bridge coupled upstream from the device. As a construct of assigning resources only upon initialization, if a device is added during runtime, resources are not dynamically allocated. Instead, the system either allocates a fixed set of resources to each root port/bridge supporting hot-swap, or is required to be restarted before the added device is able to function properly. The allocation of a fixed set of resources, called “resource padding”, causes a small amount of resources to be potentially spread across several bridge devices, preventing devices needing large amounts of resources from being allocated the required resources. Similarly, if a device is removed during runtime, resources are still allocated to a bridge device/root controller, previously above the removed device, which potentially results in a waste of resources.

### BRIEF DESCRIPTION OF THE DRAWINGS

The present invention is illustrated by way of example and not intended to be limited by the figures of the accompanying drawings.

FIG. 1 illustrates an embodiment of a controller hub to dynamically assign resources to root controllers.

FIG. 2 illustrates an embodiment of a layered hardware, firmware, and software abstraction of a system to dynamically assign resources to devices and/or root ports.

FIG. 3 illustrates an embodiment of a flow diagram for assigning resources to a newly added device.

FIG. 4 illustrates an embodiment of a flow diagram for re-assigning resources associated with a device to a resource pool.

FIG. 5 illustrates an embodiment of a flow diagram for assigning resources to devices upon system initialization.

### DETAILED DESCRIPTION

In the following description, numerous specific details are set forth such as examples of interconnects, devices, controllers, code storage, implementation, etc. in order to provide a thorough understanding of the present invention. It will be apparent, however, to one skilled in the art that these specific details need not be employed to practice the present invention. In other instances, well known components or methods, such as specific interconnect implementation, logic and circuit implementations, interrupt handlers, as well as code for operating systems, basic input/output software (BIOS), and handler routines, have not been described in detail in order to avoid unnecessarily obscuring the present invention.

The method and apparatus described herein are for managing interconnect controllers, which is specifically discussed in reference to interconnect controllers in a computer system. However, the methods and apparatus for managing interconnect controllers are not so limited, as they may be implemented on or in association with any system or integrated circuit device, such as a portable digital assistant (PDA), cell phone, or other electronic device.

Controller Hub

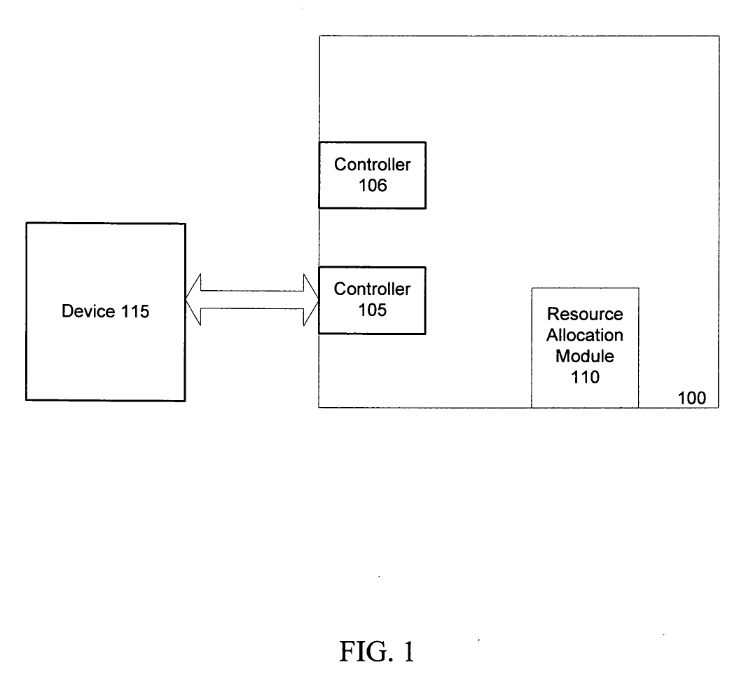

Referring to FIG. 1, controller hub 100 is illustrated. Controller hub 100 may be any integrated circuit or programmable device, such as a Field Programmable Gate Array (FPGA). In one embodiment, controller hub 100 is a hub in a computer system to communicate with interconnect devices. As an example, controller hub 100 is a interconnect controller hub (ICH) coupled to a memory controller hub (MCH), where ICH 100 is to communicate with the MCH, as well as other devices. In another embodiment, controller hub 100 is an MCH. Commonly, a combination of the MCH and ICH are referred to as a chipset, which is typically implemented on at least two different integrated circuits.

Devices coupled to hub 100 are not limited to devices internal to a computer system, as devices external to the system may also be coupled to hub 100. As examples, controller hub 100 couples to network adapters/devices, local area network (LAN) devices, audio devices, video processors/devices, storage devices, disk drives, hard drives, portable storage devices, input/output devices, cameras, personal digital assistances, display devices, printers, phones, wireless devices, faxes, and other electronic devices. Coupling is not limited to physical coupling, as wireless devices may communicate with a transmitter/receiver integrated in controller hub 100 or physically coupled to controller hub 100.

Controller/Root Port/Bridge

Controller 105 and 106 is illustrated in controller hub 100. However, from above, it is also apparent that controllers or devices, such as a local area network device/controller, may be coupled externally to controller hub 100 or integrated in controller hub 100. In one embodiment, controller 105 includes logic to communicate with a device. As a first example, controller 105 is a PCI-Express root port for communicating with PCI-Express devices. As another illustrative example, controller 105 is a network bridge to communicate with a network adapter device. In this example, assume a packet of information is received by the network adapter from an external network, such as the internet. This packet is then communicated to bridge 105, and either decoded or forwarded by bridge 105 to the correct destination.

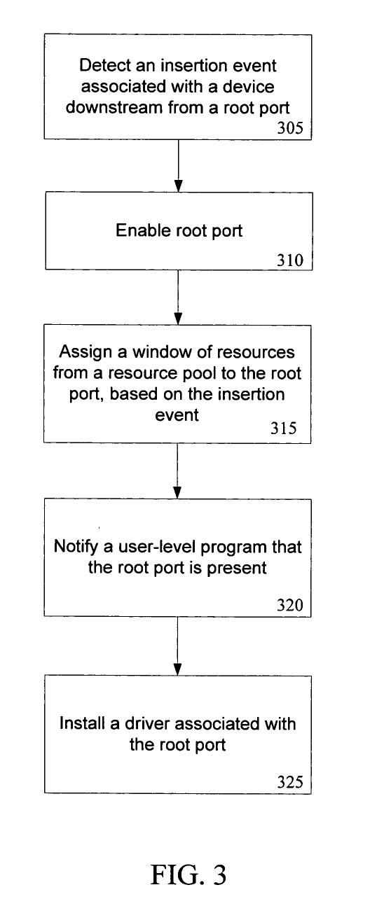

As discussed later in reference to FIG. 3, a root controller, port, or bridge is typically a controller at a level above a device in a hierarchy of an interconnect structure. In the example illustrated, device 115 is at the lowest level of the hierarchy, controller 105 is at the next higher level of the hierarchy, and another root port in controller hub 100, which is not shown and is to communicate with a higher level device, is at another level above root controller 105.

Controller 105 includes any logic, circuits, software, hardware, or code for communicating with other devices coupled internally, externally, or wirelessly to a system including controller hub 100. Other examples of controller 105 include a peripheral connection interconnect (PCI) bus controller, a PCI express (PCI-E) bus controller, a universal serial bus controller, a disk controller, a long-term storage device controller, an ATA disk controller, a SCSI controller, a Firewire controller, an audio controller, a video controller, a graphics controller, a network controller, a local area network (LAN) controller, a memory interface controller, front-side bus (FSB) controller, a serial interface controller, a parallel interface controller, and an interconnect controller, or any combination controller implementing tow or more types of interfaces, such as audio/video output/input.

Devices

Device 115 is illustrated coupled to controller 105. As stated above, device 115 includes any device commonly or potentially associated with coupling to an electronic or computer system. In a first embodiment, device 115 is an internal device in the system. The following are illustrative examples of devices typically found in a computer system: graphics cards, audio cards, network cards, hard-drives, disk-drives, storage-drives, CD/DVD ROMS, and other cards in peripheral connection interconnect (PCI) or PCI-Express (PCI-E) slots. In another embodiment, device 115 is a device externally coupled to controller hub 100. Examples of external devices include monitors, printers, mice, keyboards, routers, speakers, portable storage devices, Firewire devices, Universal Serial Bus (USB) devices, faxes, phones, scanners, and other input/output devices. Note that any of the aforementioned devices may also be wirelessly coupled to controller hub 100.

Other specific examples of potential devices include a peripheral connection interconnect (PCI) device, a PCI express (PCI-E) device, a universal serial bus device, a storage drive, a permanent storage device, an ATA storage device, a SCSI device, a firewire device, an audio device, a video device, a graphics device, a network device, a LAN device, a memory device, and an interconnect device

Often an interconnect is logically or physically viewable and/or enumerable in a hierarchy. For example, a controller is coupled to a bridge device, which is coupled to two other devices. In this example, the two devices coupled to the bridge are at the same physical level in a hierarchy, as any signal sent to the controller goes through the bridge device and to the controller. Conversely, in a ring formation no true physical hierarchy is typically ascertainable; yet, a root device that initiates communication on the ring is logically viewable as being at the highest level of a hierarchy, with every other device down a level for each device it is removed from the root device.

As used herein, the term upstream, refers to a direction up the hierarchy of connection, i.e. towards a root controller from a device or towards a higher-level device. For example, assuming controller 100 is an ICH, then controller 105 in ICH 100 is at a higher level than device 115, as any communications from device 115 are sent through controller 105 to the rest of the system. Other controllers present in an MCH or system memory may potentially be viewed as upstream from controller 105. Inversely, downstream, as used herein, refers to a direction down the hierarchy of coupling, i.e. away from a primary or root controller toward a device or away from a higher-level device. From the example above, it is apparent that device 115 is downstream from controller 105, as it is down away from higher level controller 105. Note that there may also be sideband communication channels between device 115 and other devices within or connected to hub 100 that bypass controller 105.

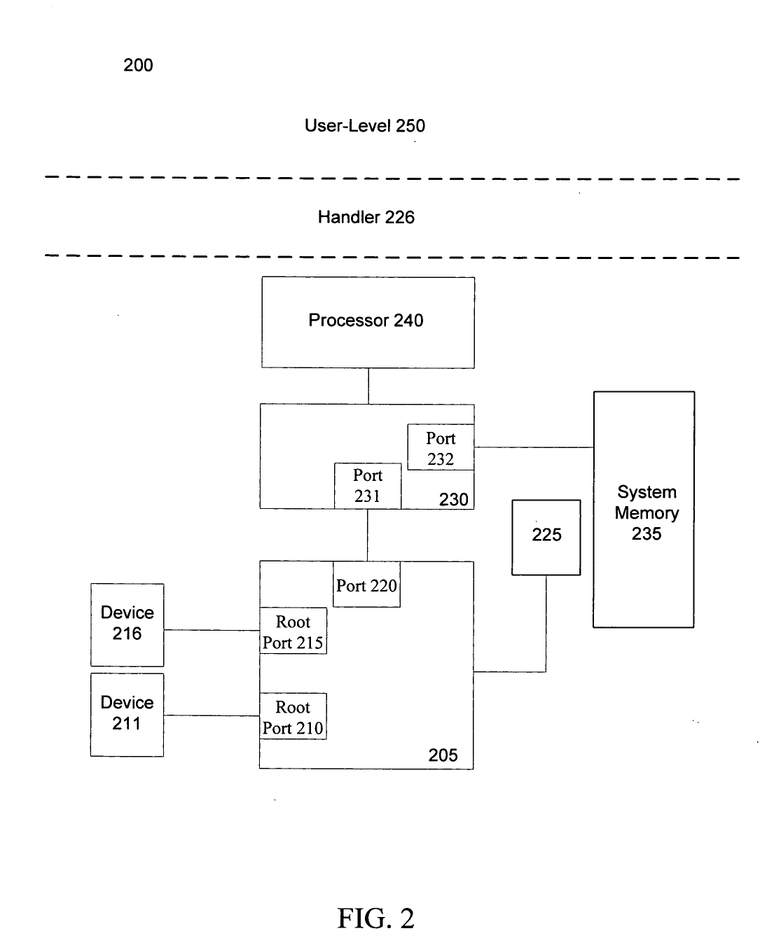

Turning to FIG. 2, a simplified example is shown, which further illustrates these principles. As an example, assume that device 211 is a PCI-E device. To send data to system memory, PCI-E device 211 forwards the data upstream to root port 210, which in turn forwards the data upstream to port 220, then to port 231, then to port 232, and finally to system memory 235. In this illustration, processor 240 is the highest level of a tree structure hierarchy, MCH 230 is at a second-level of the hierarchy, ports 231 and 232 are at a third level, port 220 is below port 231 and memory 235 is below port 232 at a fourth level, ICH 205 is at a fifth level under port 220, root ports 210 and 215 are at a sixth level under ICH 205, and devices 211 and 216 are at the lowest level, i.e. the seventh level. Therefore, a communication from device 216 to memory 235 is an upstream communication to MCH 230 then downstream to memory 235, while a communication from device 216 to device 211 is a sideband communication at the same level of the hierarchy.

Resource Allocation Module

Turning back to FIG. 1, resource allocation module 110 is illustrated. A module, such as module 110, may be implemented in hardware, software, firmware, or any combination thereof. Furthermore, module boundaries commonly vary and functions are implemented together, as well as separately in different embodiments. As an example, which is discussed in more detail below in reference to FIG. 2, resources are reserved by a flash device storing BIOS code and upon receiving a notification of addition or removal of a device, handler routines in the BIOS code are executed to dynamically assign resources correctly. From this example it is apparent that resource allocation module 110 may include hardware, such as flash memory, firmware, such as the combination of BIOS on a flash memory device, and software, such as the BIOS code, as well as cross boundaries of other modules and hardware, such as including logic in an ICH and firmware coupled to ICH 100.

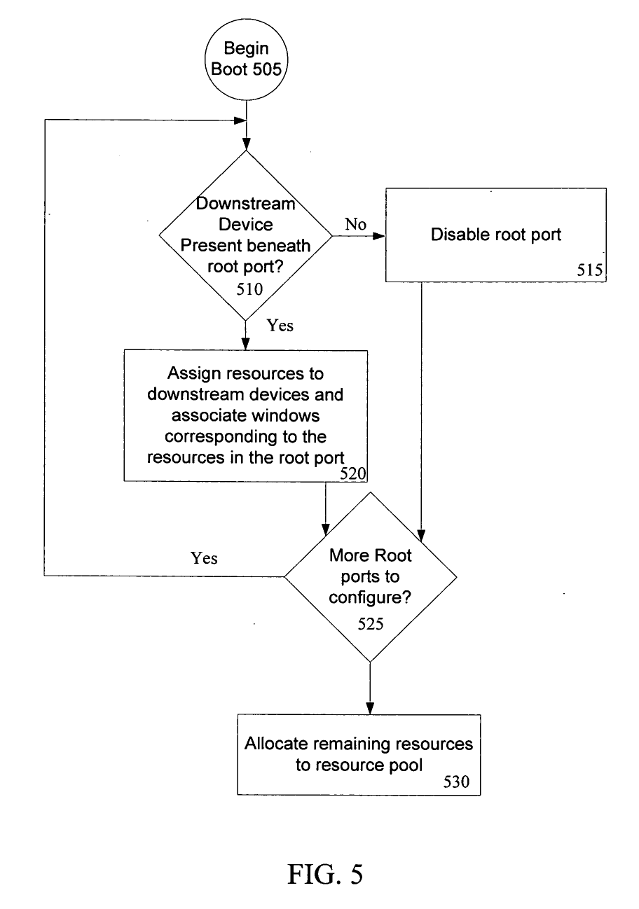

Resource allocation module 110 is to dynamically assign resources to controllers, such as controller 105. Upon system boot or initialization, resources are assigned to devices coupled to controller 105/106, windows for those resources are assigned to controllers 105/106, and the remaining resources not assigned to a specific device, i.e. a pool of resources, are assigned to/reserved by resource allocation module 110, as demonstrated below in reference to FIG. 5. Resources for devices refer to input/output (I/O) addresses, memory locations, and/or interconnect/bus numbers, while resources in reference to a controller, bridge or root port refer to a window encompassing downstream device resources. As an example of assigning resources, 1 GB of memory in an exemplary address range expressed in hexadecimal of 0x00000000 to 0x3FFFFFFF of memory is allocated and assigned to device 115 and/or a window of 4 k-6 k of I/O (0x1000-0x17FF) space is associated with device 115. Here, the memory space windows of 0x00000000 to 0x3FFFFFFF and the I/O space window of 4 k-6 k (0x1000-0x17FF) is allocated and assigned in controller 105 upstream from device 115 in order to associate the resources with device 115 in controller 105.

Note that associating, assigning, or allocating a resource or resources to a controller, root port, or bridge device, such as controller 105, may be accomplished in any number of ways. In a first embodiment, the resource is associated with device 115 in controller 105. As an example a root port or controller, such as controller 105, includes positive decode logic to recognize when an access or operation is within a window or range. If the access or operation is within the window associated with device 115 coupled to controller 105, then controller 105 forwards the access to device 115. Here, assigning resources to device 115 in controller 105 includes programming or storing a window in controller 105 to associate the resource with device 115.

For example, assume device 115 is a PCI-E device and a memory space of 1 GB in a system memory with a hexadecimal expressed window of 0x40000000 to 0x7FFFFFFF is newly associated with PCI-Express device 115. Therefore, in controller 105 the window of 0x40000000 to 0x7FFFFFFF is associated with device 115 through storage of 0x40000000 to 0x7FFFFFFF in a storage element or a plurality of storage elements in controller 105 or other positive decode logic. Here, the window may be represented by any manner including storing values to represent 0x40000000 and 0x0x7FFFFFFF as boundaries or storing a base, such as 0x40000000, and a size of 0x40000000, i.e. 1 GB. Consequently, an access to memory address 0x60000000 is within the address window associated with device 115. Similarly, if the window 0x000000 to 0x0003FF of I/o space is associated with device 115 in controller 105, then an access referencing I,O address 0x000200 is recognized by controller 105, as within the window assigned to device 115, and controller 105 forwards the access downstream to device 115.

In some interconnect implementations, resource windows, such as a memory space, are viewed logically by controllers/devices different from physical addresses of the resource windows. Note that above, exemplary memory addresses of 0x4000000, 0x6000000, and 0x0x7FFFFFFF are used to illustrate operation. However, a window physically may include a non-contiguous grouping of smaller windows or offsets within a system memory having different physical addresses. Yet, a device, such as device 115, and a controller, such as controller 105, may view this memory as a continuous address space. Commonly, a physical memory address or range of addresses are referred to as host physical addresses (HPAs) or a range of host physical addresses (HPAs), while guest software and devices sometimes potentially view a domain or address space assigned to it as a device virtual address (DVA) space or guest physical address (GPA) space.

Therefore, in another embodiment, associating a resource with device 115 in controller 105 includes storing a DVA space or GPA space in controller 105 that references the HPA space to be associated with device 115. As another example, associating resources, such as a window of bus numbers, with device 115 includes storing a representation of the window of bus number in controller 105. Here once again, bounds or a starting/base address and a size value may be stored in controller 105 to establish a window of bus numbers associated with device 115. Controller 105 may also include logic to convert between HPAs and GPAs. Alternatively, controller 105 may store the same window or range in multiple formats, such as a virtual window and a physical window, for upstream, downstream, and sideband accesses.

As a consequence, resources from a resource pool may be associated with device 115 in controller 105, through storing or establishing the windows/ranges in controller 105. Furthermore, a resource pool may include a reference to a plurality of I/O addresses, system memory addresses, or bus numbers not associated with any particular or specific interconnect device. Alternatively, a pool of resources does not include any specifically assigned resources, but rather includes a portion or all I/O addresses, bus numbers, and memory space not allocated to interconnect devices and/or not accessible by a kernel-level program, such as an operating system.

This pool of resources is then available to be assigned to a currently present device requiring additional resources or a newly added device by associating new windows of the resources in upstream controllers/bridges. As stated above, upon system boot, remaining resources that form a resource pool may be assigned to a pooling device, such as resource allocation module 110 or a firmware device, to reserve the resources to be dynamically assigned at a later time. In another sense, resource allocation module 110 or a firmware device reserves the pool of resources in that the pool of resources are inaccessible to kernel-level programs.

Allocation/De-Allocation Requests

In one embodiment, resource allocation module 110 is to dynamically allocate a window of resources from a pool of resources to controller 105 based on an allocation request. As an example, assume initially that, upon boot, resources are assigned to device 115, controller 106 is disabled as no device is coupled downstream from controller 106, and the remaining resources are assigned to resource allocation module 110 as a pool of resources.

Upon adding a device, not shown, under controller 106, an allocation request is generated. An allocation request may either be a request from a device already present, such as device 115, or a notification, such as an interrupt, of a newly inserted/added device. Allocation and de-allocation requests, such as insertion and ejection notifications, are discussed in more detail below in the insertion/ejection events section. Based on the allocation request, controller 106 is enabled and resources are allocated to the new device, and a window of resources are assigned/allocated to controller 106 from the resource pool, which was initially assigned to resource allocation module 110, to associate the new devices resources in controller 106 with the new downstream device.

As an illustrative example, initially, upon boot of a system including ICH 100 and device 115, device 115 is assigned a 512 MB window represented as 0x00000000 to 0x1FFFFFFF of memory space, where the window is associated with device 115 in positive decode logic in controller 105. A remaining 3.5 GB of memory space is reserved by resource allocation module 110. Note that this example is a simplified example with abstract numbers, as typically memory space for a desktop machine is between 1 GB and 8 GB. However, for servers and future machines, memory spaces will likely grow. In one case, device 115 may generate an allocation request, where device 115 asynchronously generates an allocation request for more resources, such as memory space. In another example, controller 105 writes to a register, such as a base address register (BAR), and receives values that are read back out of the register to determine an amount of resources, such as memory space, needed by device 115. Assuming device 115 requires 512 MB more of memory space, another 512 MB of the 3.5 GB of memory space in the resource pool reserved by resource allocation module 110 is assigned to device 115. The new window of 0x00000000 to 0x3FFFFFFF is assigned/allocated to controller 105 to associate device 115's new resources with device 115 downstream from controller 105.

After fulfilling the allocation request by device 115, assume that another device is connected to controller 106. Since no downstream device was present during boot of the system, controller 106 was not allocated any window for resources. Based on the insertion of the new device, an allocation request, in the form of an insertion interrupt, is generated. If controller 106 is disabled, it is enabled, which may include supplying power to controller 106 or bring controller 106 up to a higher-power state. As above, a communication protocol between the new device and controller 106 may be used to determine the amount of resources to assign to the new device. Assuming 1 GB is to be allocated to the new device, then 1 GB, which is represented by hexadecimal addresses 0x40000000 to 0x7FFFFFFF, of the remaining 3 GB of memory space assigned to the resource pool is assigned to controller 106 to associate the window of 0x40000000 to 0x x7FFFFFFF with the new device.

Also note that resources may be assigned to the controller itself upon addition of a new device. For example, assume a controller is disabled and hidden, then upon addition of a new device a window of resources from the resource pool is also associated with controller 106 in an upstream controller.

After adding the new device, the resource pool includes an unassigned memory space of 0x80000000 to 0x100000000, i.e. 2 GB, a window of 0x00000000 to 0x40000000 is associated with device 115 in controller 105, and a window of 0x40000000 to 0x7FFFFFFF is associated with the new device in controller 106. These memory addresses, sizes, windows, etc. are purely exemplary, as any windows, amounts of memory, etc. may be used. For example, a typical total amount of system memory available in an average desktop system is anywhere from 128 MB to 2 GB. In addition, above it was stated that the resource pool includes all 2 GB of remaining resource space; however, an operating system or other kernel-level program may have access to or reserved a portion of the remaining 2 GB, which reduces the resource pool available. Furthermore, as stated above, the resource pool may include other resources, such as I/O space or bus numbers.

In the alternative to a request for additional resources, resource allocation module 110 may also dynamically de-allocate resources from the controller/device and re-allocate the resource back to the pool of resources upon a de-allocation request. Here, de-allocation operates in a similar manner to allocating resources. Instead of a request for more resources, a device may offer a forfeit of some amount of resources. Additionally, a device upon removal has its resources de-allocated and reassigned to the resource pool. Continuing the example from above, if the new device is removed, after the resources are assigned to it, then a de-allocation request in the form of an ejection interrupt is generated. The 1 GB window of memory, represented by 0x40000000 to 0x x7FFFFFFF, is re-assigned from controller 106 to the resource pool. As discussed below, since no downstream device are connected to controller 106 any longer, controller 106 may be fully disabled/hidden from view of an operating system.

An Embodiment of a System

Referring to FIG. 2, an embodiment of a layered abstraction of software, firmware, and hardware in a system for dynamically allocating resources is illustrated. System 200 includes a processor 240 coupled to memory controller hub (MCH) 230, which may be part of a chipset including MCH 230 and interconnect controller hub (ICH) 205. Processor 240 is any processing element to operate on data or execute instructions, such as a microprocessor, a processing cell element, a microcontroller, a FPGA, an embedded controller, or other processor. In an example where processor 240 is a microprocessor, it is capable of serial, parallel, fixed point, floating point, out-of-order, speculative, and/or transactional execution. Processor 240 may be based on any architecture, such as x86, IPF, XScale, or other architecture. MCH 230 is coupled between processor 240 and system memory 235. MCH 230 may also include ports/controllers, like ports 231 and 232, for communicating both with memory 235 and ICH 205, as well as other devices, such as processor 240 or a video card.

System memory 235 includes any random access memory (RAM), such as a random access memory (RAM), such as a static RAM (SRAM) or dynamic RAM (DRAM), device. Unlike a non-volatile memory, a volatile RAM device does not usually store values, when no power is supplied to the device. Examples of common RAM devices include double-data rate (DDR) RAM, synchronous DRAM (SDRAM), non-synchronous DRAM, and extended data out DRAM (EDO RAM).

In a specific illustrative example, assume that devices 211 and 216 are PCI-E devices, root ports 210 and 215 are PCI-E ports/controllers for coupling devices in a hierarchy, and port 220 is a PCI-E port/controller integrated in ICH 205 for communicating with MCH 230.

Insertion/Ejection Events

As stated above, an allocation request includes any signal representing resources that are to be allocated/assigned to a port, such as ports 215 and 210, or a device, such as devices 211 and 216. In one embodiment, an allocation request is a request from device 211 that it requires more of a resource, such as I/O space, memory space, or bus numbers. In another embodiment, an allocation request includes a response to a write or read to a register, such as a base address register (BAR), in device 211 that determines how much of a resource device 211 requires. In one case, the amount of resource is determined by detecting which bits during the write/read are sticky in the register on device 211.

Alternatively, an allocation request includes a insertion notification, such as an insertion interrupt, based on an insertion event associated with device 216. Here, when device 216 is added downstream from root port 215, an insertion interrupt is generated. Based on that insertion interrupt a window of resources are allocated from a resource pool to root port 215. In another embodiment, an insertion event includes virtually adding the downstream device under the root port in a plug-n-play (PnP) manager within an operating system (OS). Therefore, an insertion event includes the physical insertion of a downstream device, a virtual insertion of a downstream device with a plug-n-play manager associated with an operating system, and an interrupt generated based on a physical or a virtual insertion of a downstream device.

Similarly, a de-allocation request includes an ejection interrupt, an ejection notification, or a signal representing that a device, such as device 211, does not require or is not utilizing some amount of resources assigned to it. Generally, removal of a downstream device may occur in two ways: (1) the device is hidden/removed by the user from view of a user-level program, such as an operating system (OS), which is referred to as a graceful removal; or (2) a device is physically removed from the system without previously notifying an OS, which is referred to as a surprise removal. Therefore, an ejection event includes a surprise physical ejection of the downstream device, a graceful ejection of the downstream device with a plug-n-play manager from an associated operating system, and an interrupt generated based on a physical or virtual ejection of the downstream device.

Detection Module

A detection module, not shown, may be present in ports 210 and 215, present in controller 205, vary across hardware boundaries, and include software components. A detection module is to determine if a device is present, inserted, or ejected. Consequently, upon an insertion or removal, as discussed above, a detection module detects the insertion or removal and performs a corresponding function. For example, a detection module includes logic to generate an insertion interrupt upon insertion of a device, such as device 216, under root port 215. The logic may also generate an ejection interrupt upon a removal of device 216.

Furthermore, the detection module may also include a handler routine that, when executed, is to notify a user-level program that the device is present or removed based on the corresponding insertion or ejection interrupt. Routines to handle insertion and ejection interrupts are discussed in more detail below in the firmware/handler code/BIOS section. In another embodiment, the detection module is also to access a register in device 216, when device 216 is present under root port 215, to determine an amount of the resource required to be allocated to device 216.

Firmware/Handler Code/Bios

As stated above, FIG. 2 illustrates a layered abstraction of software/code to be executed on underlying hardware. In one embodiment, handler code executed on hardware in system 200 is to handle an insertion or ejection event. As a first example, a first insertion notification, such as an insertion interrupt, is generated upon connecting device 216 downstream from root port 215, as discussed above. Handler 226 traps the insertion interrupt to service the interrupt by performing an allocation/assigning of resources function.

Handler 226 includes any code or other form of handler for servicing physical or virtual insertion or ejection notifications. In one embodiment, handler 226 includes handler routines stored on firmware device 225. Here, firmware device 225 may be a basic input/output software (BIOS) device. Often BIOS code is used to initialize a system and hand-off control to a user-level program such as an operating system. However, at runtime, BIOS code is often used as a handler, when executed, to service hardware interrupts and communicate with higher level software, such as user-level 250.

Underlying hardware to store handler code 226 may be any storage device, such as a random access memory (RAM) or non-volatile memory device. As a specific example of non-volatile memory, device 225 is an erasable programmable read-only memory (EPROM). An EPROM and an electrically erasable PROM or EEPROM device is often referred to as a flash device, since the device is “flashed” or electrically erased/programmed. The two common types of flash memory include NOR and NAND flash memory, which refers to the types of transistors and memory array physical organization used in the device. Both types of flash memory store information in an array of transistors, which are referred to as cells. Traditionally, each cell stores 1-bit of information per cell; however, multi-bit cells are also currently used to store multiple bits per cell of a flash device.

A flash device may include a plurality of features, such as locking arrays, manufacturer and customer information, write buffers, and some form of processing element integrated on the flash device. As an example, flash device 225 includes a micro-controller to execute handler code 226 stored on flash memory device 225.

Although BIOS code stored on a BIOS chip, such as a flash device, is specifically discussed as handler code 226, handler code 226 is not so limited. In fact, handler code 226 may be implemented in firmware or logic present on ICH 205, part of user-level 250, or temporarily stored in system memory 235. Furthermore, handler code 226 is not limited to local execution on device 225, but rather may be executed elsewhere in system 200, such as on processor 240. For example, processor 240 is capable of operating in handler or system management mode, where processor 240 executes handler code 226 stored either in system memory 235 or locally on processor 240. Here, when an interrupt is generated execution in processor 240 is re-vectored to a handler that either handles the interrupt directly, jumps execution to a handler to service the interrupt, or provides notification to some program executing at user-level 250 to service the interrupt.

To illustrate operation of system 200, the following illustrative example assumes that handler code 226 is part of BIOS code stored on firmware device 225, which is a flash memory device, and root ports 215 and 210 are part of a PCI-Express bus. During initialization of system 200, when executing BIOS code, I/O space, memory space, and bus numbers are assigned to devices 211 and 216.

To provide an oversimplified example of the resources to further the example, 4 KB of I/O space represented by a window having a base address of 0x00000 plus a size value of 0x01000, i.e. 4 KB, 1 GB of memory space represented by a window having a base processor-relative address of 0x00000000 plus a size value of 0x40000000, i.e. 1 GB, and a bus number of 1 is associated with device 211 in positive decode logic in root port 210. In addition, 4 KB of I/O space represented by a window with base address 0x01000 plus a size value of 0x01000, i.e. 4 KB, 1 GB of memory space represented by a window having a base virtual address of 0x40000000 plus a size value of 0x40000000, i.e. 1 GB, and a bus number of 2 is assigned to device 216. Since no other device are connected downstream from root ports in MCH 230 or ICH 205, which we assume have a bus number of 0, the remaining resources of 56 KB of I/O space, 2 GB of memory space, and 253 bus numbers are reserved by firmware device 225 to form a pool of resources. Therefore, the pool of resources may be, by default, be assigned to/reserved by firmware device 225. After this exemplary initial assignment, control is then handed over to an operating system (OS) to be executed at kernel or user-level 250. Note from above that reservation may simply include that the pool of resources is not assigned to some other device and is inaccessible by an operating system.

When a graceful removal of device 216 occurs, device 216 and potentially root port 215 is/are removed from view of kernel-level 250. After removal of device 216 from system 200 by either graceful or surprise removal, handler code 226, i.e. BIOS code executed at runtime, handles the ejection notification. The windows of resources previously associated with device 216 in root port 215 are re-assigned by handler code 226, when executed, to the resource pool. As a result, the resource pool, after re-assignment, includes 60 KB of I/O space, 3 GB of memory space, and 254 bus numbers.

In one embodiment, re-assignment includes invalidating or removing the 4 KB window of I/O space, the 1 GB window of memory space, and the stored bus number in root port 215. Then, those windows of resources are no longer associated with a bus device, such as a root port or bridge, and are therefore, returned to the resource pool. In another embodiment, re-assigning the windows or resources to the resource pool includes assigning the resources to a pooling device, such as the BIOS firmware.

Continuing the example, if device 216 is re-connected to system 200 either physically or wirelessly, then resources are assigned from the pool of resources to root port 215, which is then re-added to the view of the OS. For example, when device 216 is connected downstream from root port 215, a detection module detects the insertion either through an asynchronous generation of an interrupt or a synchronous response to a pooling of the inserted device. For example, port 215 or a portion of port 215 may be periodically enabled from a low-power state to determine if device 216 is now present, and then disabled, if no device is detected.

Based on the insertion notification, handler code 226, when executed, assigns a portion of the resource pool, which may be assigned to/reserved by firmware device 225, to root port 215, i.e. I/O space, memory space, and/or bus numbers may be associated with device 216 in root port 215. Assigning of resources may be carried out as discussed above.

An Embodiment of a Method for Assigning Resources Based on an Insertion Event

Turning to FIG. 3, an embodiment of a flow diagram for a method of assigning resources to a root port based on an insertion event. In flow 305, an insertion event associated with a device downstream from a root port is detected. As stated above, insertion of a downstream device during runtime may be detected in any number of ways. Logic on the device may initiate an insertion notification to be received by a root port coupled upstream from the device, which is to be trapped and serviced by an interrupt handler. Alternatively, the root port coupled upstream may periodically poll the slot downstream to see if a device has be connected. Thirdly, there may be some component or circuit external to the controller or the device which can generate the insertion event interrupt, such as detection circuitry.

A controller includes any interface module for communicating with a downstream device. A device includes any internal or external device to be coupled to a system over an interface. As stated above, common examples of interfaces that are known today include PCI, PCI-X, PCI-Express, USB, SATA, wireless interface, front-side bus (FSB), a memory interface, a video interface, and a network interface.

In flow 310, the root port is enabled. In some implementations a root port is always enabled, so there is no requirement that the port be enabled. However, if a port is disabled, when no downstream device is present, the root port is enabled to communicate with the downstream device. Furthermore, in an implementation where only a portion of a root port, i.e. detection circuitry, is periodically enabled to detect if a device has been added, the rest of the root port is enabled. Often, when a root port is disabled, it is also removed from view of a kernel-level program, such as an OS. Therefore, enabling of a root port may also encompass the addition of the root port to visibility in the OS. However, this is discussed in more detail in reference to flows 320 and 325.

In flow 315, a window of resources from a resource pool is assigned to the root port based on the insertion event. In one embodiment, based on the insertion event, handler code is executed to assign a window of I/O addresses, a window of memory address, a window of bus numbers, or a combination of thereof to the root port and/or to the device based on the requirements of the inserted device. As stated above, these windows are assigned to a root port by associating the window of resources in the root port to which the downstream device was added. Windows associated in ports/controllers upstream from the root port may also reflect new resource assignments of downstream devices/ports to ensure correct forwarding of accesses and operation throughout the hierarchy of the interconnect structure.

Next, in flow 320 a user-level program is notified that the root port is present. In the case, where a root port is disabled and hidden from a user-level program, such as an OS, the root port is made visible again to the OS. As an example, the handler code, in addition to assigning resources, also notifies a plug-n-play (PnP) manager associated with an OS that the root port and device are now present. Lastly, after notification, a PnP manager typically installs a driver associated with the root port in a memory space associated with the root port, as in flow 325. After enumerating the root port, the a similar method may be followed by the hardware, handler, PnP and operating system to enumerate the downstream devices, assign resources available via the root port resource windows, and install appropriate drivers.

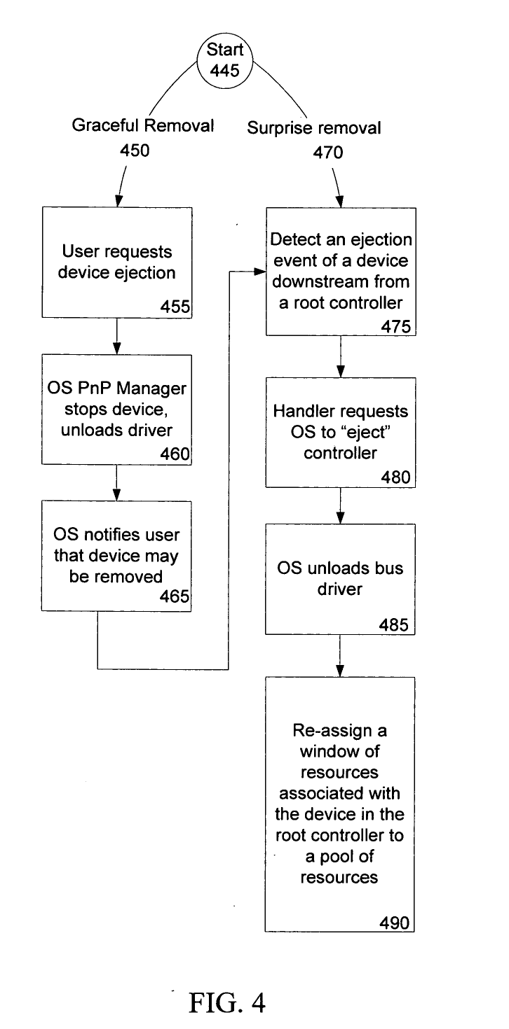

From the discussion above, it is apparent that the flows depicted in FIG. 3, as well as FIGS. 4-5, need not be performed in the same order. For example, as part of enabling root port, flow 310, 320, and 325 may all be performed before flow 315.

An Embodiment of a Method for Re-Assigning Resources Based on an Ejection Event

Turning to FIG. 4, an embodiment of a flow diagram for a method of re-assigning resources to a resource pool based on an ejection event is illustrated. It is assumed that the system is initialized and an OS is executing, i.e. runtime execution, at starting point 445. Typically, there are two types of removal of devices from a system. The first way is graceful removal where a user requests ejection of a device from the an OS in flow 445, a PnP manager associated with the OS stops the device in the OS and unloads a device driver associated with the device in flow 460, and the OS notifies the user that the device may be safely removed in flow 465.

The second type of removal, is a surprise removal 470 where a device is physically removed without prior notification to an OS. Whichever way a device is removed, in flow 475 an ejection event of a device downstream from a root controller is detected. In other words, either through a graceful physical removal or a surprise physical removal, the system detects a removal/ejection of the device and initiates a removal of the controller from a view of a kernel-level program, as discussed below.

In flow 480, a handler handling the ejection event/notification, which may be executed on firmware or a processor, handles the ejection notification by requesting an operating system to eject the root controller, as no downstream device is connected downstream from the root controller any longer. In flow 485, the OS unloads a driver associated with the root controller.

Next, in flow 490 a window of resources associated with the device in the root controller is re-assigned to a pool of resources. As stated above, the pool of resources may be reserved by a pooling device or simply reserved, in that, they are not assigned to any device or accessible by the operating system. The pool of resource may include any combination of a plurality of I/O addresses, memory address, and bus numbers. In one embodiment, the pooling device is a flash memory device storing the handler code. However, a pooling device may be any physical device or virtual construct for assigning resources to, which are not currently assigned to any specific bus device and are able to re-assigned to a device based on an allocation request.

An Embodiment of a Method for Assigning Resourcses Upon Initialization of a computer System

Turning to FIG. 5, an embodiment of a flow diagram for assigning resources upon boot/initialization of a computer system is illustrated. In flow 505, a boot process is started. Often a boot process consists of executing instructions/code out of a flash memory device. In one embodiment, the code is BIOS code to initialize a platform. The BIOS code may be executed by a local processing element, such as a host processor or micro-controller present on the flash device storing the BIOS code, or a remote processor. Often during the boot sequence, system components, such as system memory, are initialized. However, the boot process initializes components in any order based on the design and code. For example, in one embodiment, boot code is stored in an Execute in Place (XiP) architecture, where initialization instructions are substantially stored and executed in order.

In decision flow 510, it is determined if a downstream device is present beneath a root port. If no downstream device is present, then the root port is disabled in flow 515, which may include putting the root port in a low-power state and/or configuring it in a manner that would cause it not to be visible or enumerable by an operating system. In decision flow 525, if there are more root ports in the system to configure, then the flow returns to flow 510.

If a device is present beneath the current root port, then resources, such as memory space, I/O space, and bus numbers, are assigned to the downstream device and resource windows corresponding to the resources are associated with the downstream device in the root port. As above, associating resources in the root port includes assigning resources to the downstream device in the root port by storing a window encompassing the resources assigned to the downstream device. After assigning resources to the current root port, it is determined if there are any more root ports to configure in flow 525.

If there are no other root ports, then the remaining resources are allocated to a resource pool in flow 530. Allocating resources to a resource pool may be done as discussed above. For example, any remaining resources are assigned to a pooling device, such as firmware storing the BIOS code, to form a pool of resources to be added to by removed devices and allocated from by inserted devices.

An Embodiment of an Article of Manufacture

The embodiments of methods, software, firmware or code set forth above may be implemented via instructions or code stored on a machine-accessible or machine readable medium which are executable by a processing element. A machine-accessible/readable medium includes any mechanism that provides (i.e., stores and/or transmits) information in a form readable by a machine, such as a computer or electronic system. For example, a machine-accessible medium includes random-access memory (RAM), such as static RAM (SRAM) or dynamic RAM (DRAM); ROM; magnetic or optical storage medium; flash memory devices; electrical, optical, acoustical or other form of propagated signals (e.g., carrier waves, infrared signals, digital signals); etc. For example, the software or code set forth above may be stored in a readable medium, such as executable code stored in a database to be transferred over a network, where when executed, performs the methods discussed above.

As can bee seen from the discussion above, efficient hot-swap of devices in and out of a system is potentially enabled through dynamic allocation of resources. Instead of having to reboot a system every time a configuration of devices or the resource needs of downstream devices exceed fixed windows of resources allocated to upstream controllers. For example, previously resources were spread thin over controllers by allocating a fixed window of resources to each controller. However, upon addition of a new device under a controller with a fixed window, the system would have to restart for the device to operate properly, if the device required more resources than the fixed window provided for. Instead, by allowing dynamic allocation of windows of resources among controllers, when adding a device resources are dynamically allocated from a pool of resources to a controller upstream from the added device to ensure proper operation during runtime without a reboot. In addition, when a device is removed the window of resources assigned to the upstream controller may be assigned back to the pool of resources to be re-allocated to another controller, instead of leaving the window of resources statically associated with the controller with all of its downstream devices removed. Furthermore, BIOS code operating as a handler at runtime is an existing efficient method for both assigning resources and notifying a user-level program, such as OS, of insertion and ejection of both root ports/controllers and devices.

In the foregoing specification, a detailed description has been given with reference to specific exemplary embodiments. It will, however, be evident that various modifications and changes may be made thereto without departing from the broader spirit and scope of the invention as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

What is claimed is:

1. An apparatus comprising:
a controller to communicate with a device; and
a resource allocation module to dynamically allocate a window of a resource from a pool of resources to the controller based on an allocation request.

2. The apparatus of claim 1, wherein the controller is selected from a group consisting of a peripheral connection interconnect (PCI) bus controller, a PCI express (PCI-E) bus controller, a root port, a root controller, a universal serial bus controller, a disk controller, a long-term storage device controller, an ATA disk controller, a SCSI controller, a firewire controller, an audio controller, a video controller, a graphics controller, a network controller, a LAN controller, a memory interface controller, an interconnect controller, and a combination audio/video controller.

3. The apparatus of claim 1, wherein the device is selected from a group consisting of a peripheral connection interconnect (PCI) device, a PCI express (PCI-E) device, a universal serial bus device, a storage drive, a permanent storage device, an ATA storage device, a SCSI device, a firewire device, an audio device, a video device, a graphics device, a network device, a LAN device, a memory device, and an interconnect device.

4. The apparatus of claim 1, wherein the window of the resource is selected from a group consisting of a window of input/output addresses, a window of memory addresses, and a window of interconnect numbers.

5. The apparatus of claim 1, wherein the resource allocation module is also to dynamically de-allocate the window of the resource from the controller and re-allocate the window of the resource back to the pool of resources upon a de-allocation request.

6. The apparatus of claim 5, wherein an allocation request includes an insertion interrupt associated with an insertion of the device under the controller, and a de-allocation request includes an ejection interrupt associated with physical removal of the device from under the controller.

7. The apparatus of claim 6, further comprising a detection module to generate the insertion interrupt upon insertion of the device and the ejection interrupt upon the physical removal of the device, wherein the detection module also includes a handler routine that, when executed, is to
notify a user-level program that the device is present based on the insertion interrupt, and
notify the user-level program that the device is not present based on the ejection interrupt.

8. The apparatus of claim 7, wherein detection module is also to access a register in the device, when the device is present, to determine an amount of the resource required to be allocated to the device.

9. The apparatus of claim 5, wherein an allocation request includes a request for an additional amount of the resource.

10. The apparatus of claim 5, wherein the resource allocation module includes code stored in a firmware device.

11. The apparatus of claim 10, wherein the firmware device is a flash memory device, and wherein the code stored in the firmware device is basic input/output software (BIOS).

12. The apparatus of claim 10, wherein the pool of resources is, by default, reserved by the firmware device, and wherein allocating the window of the resource from the pool of resources to the controller comprises storing a base value and a size value of the window of the resource in the controller.

13. An apparatus comprising:
a firmware device to store code that, when executed, is to
assign a first portion of a resource pool reserved by the firmware device to a root port to be coupled upstream from a downstream device, upon an insertion event associated with the downstream device, and
return the first portion of the resource pool assigned to the first root port to the resource pool, upon an ejection event associated with the downstream device.

14. The apparatus of claim 13, wherein the code, when executed, is also to assign a second portion of the resource pool reserved by the firmware device to the root port, upon an additional resource request from the downstream device.

15. The apparatus of claim 13, wherein the root port is a root port in a peripheral connection interconnect express (PCI-Express) bus, and wherein the downstream device is a PCI-Express device.

16. The apparatus of claim 15, wherein the firmware device includes flash memory, and wherein the code to be stored in the flash memory includes basic input/output software (BIOS) code.

17. The apparatus of claim 16, wherein an insertion event includes an insertion of the downstream device under the root port, and wherein an ejection event includes an ejection of the downstream device from under the root port.

18. The apparatus of claim 16, wherein an insertion interrupt is generated based on the insertion of the downstream device under the root port and the BIOS code, when executed, assigns the portion of the resource pool to the root port, and wherein an ejection interrupt is generated based on the ejection of the downstream device from under the root port and the BIOS code, when executed, re-assigns the portion of the resource pool assigned to the root port to the firmware device.

19. The apparatus of claim 13, wherein an insertion event includes virtually adding the downstream device under the root port in a plug-n-play (PnP) manager within an operating system (OS), and wherein an ejection event includes virtually removing the downstream device from under the root port in the PnP manage within the OS.

20. The apparatus of claim 13, wherein the resource pool includes a window of input/output (I/O) space, and wherein assigning a first portion of a resource pool includes assigning a first portion of the window of I/O space.

21. The apparatus of claim 13, wherein the resource pool includes a window of memory space, and wherein assigning a first portion of a resource pool includes assigning a first portion of the window of memory space.

22. A system comprising:
a controller hub including a root port to communicate with a downstream device;
a firmware device coupled to the controller hub to store handler code that, when executed, is to
associate a window of a resource from a pool of resources with the downstream device in the root port based an insertion event, and
re-associate the window of the resource, which are associated with the downstream device in the root port, with the pool of resources, based on an ejection event; and
a processing element to execute the handler code based on the insertion event or the ejection event.

23. The apparatus of claim 22, wherein the firmware device is a flash memory device, the handler code is basic input/output software (BIOS) code, and the processing element is a micro-controller present on the flash memory device.

24. The apparatus of claim 22, wherein the processing element is a microprocessor coupled to the controller hub.

25. The system of claim 22, wherein controller hub is an interconnect controller hub (ICH), the root port is a peripheral connection interconnect express (PCI-Express) root port, and the downstream device is a PCI-Express device.

26. The system of claim 22, wherein the insertion event includes an event selected from a group consisting of a physical insertion of the downstream device, a virtual insertion of the downstream device with a plug-n-play manager associated with an operating system, a virtual insertion of the root port with a plug-n-play manager associated with an operating system, an interrupt generated based on a virtual insertion of the root port, and an interrupt generated based on a physical or a virtual insertion of the downstream device.

27. The system of claim 22, wherein the ejection event includes an event selected from a group consisting of a surprise physical ejection of the downstream device, a graceful ejection of the downstream device with a plug-n-play manager from an associated operating system, a virtual ejection of the root port, and an interrupt generated based on a physical or virtual ejection of the downstream device.

28. The system of claim 22, wherein the pool of resources includes a plurality of I/O addresses, a plurality of memory addresses, and a plurality of bus numbers.

29. The system of claim 28, wherein associating the window of the resource from the pool of resources with the downstream device in the root port comprises: storing a window of a portion of the resource in the root port.

30. The system of claim 29, wherein re-associating the window of the resource with the pool of resources comprises: removing the window of the portion of the resource from the root port, , wherein the resource is selected from a group consisting of the plurality of I/O address, the plurality of memory address, and the plurality of bus numbers.

31. The system of claim 22, wherein the handler code, when executed, is also to increase a size of the window of the resource from the pool of resources based on an additional resource request from the downstream device.

32. A method comprising:
detecting an insertion event associated with a device downstream from a root port;
assigning a window of resources from a resource pool to the root port, based on the insertion event.

33. The method of claim 32, further comprising:
generating an insertion event interrupt, after detecting the insertion event.

34. The method of claim 33, wherein assigning resources from a resource pool to the root port, based on the insertion event comprises:
executing handler code to handle the insertion event interrupt, wherein handling the insertion event interrupt includes associating the window of resources from the resource pool, in the root port, with the device downstream from the root port.

35. The method of claim 34, wherein handling the insertion event interrupt further includes enabling the root port, if the root port is disabled, before associating the window of resources with the root port.

36. The method of claim 35, wherein handling the insertion event interrupt further includes:
notifying a user-level program that the root port is present; and
installing a driver associated with the root port.

37. The method of claim 32, wherein the resource pool includes a range of I/O addresses, a range of memory addresses, and a range of bus numbers, and wherein the range of I/O address, the range of memory addresses, and the range of bus numbers are, by default, assigned to a firmware device.

38. The method of claim 34, assigning a window of resources from a resource pool to the root port comprises: associating in the root port a window, selected from a group consisting of a window within the range of I/O addresses, a window within the range of memory address, and a window within the range of bus numbers, with the device downstream from the root port.

39. A method comprising:
detecting an ejection event of a device downstream from a root controller;
re-assigning a window of resources associated with the device in the root controller to a pool of resources.

40. The method of claim 39, wherein an ejection event comprises a graceful removal from a user-level program.

41. The method of claim 39, wherein an ejection event comprises a physical surprise removal of the device.

42. The method of claim 39, wherein re-assigning a window of resources associated with the device in the root controller to a pool of resources associated with a pooling device comprises executing handler code to handle the ejection event, wherein handling the ejection event includes: de-associating the window of resources with the device in the root controller.

43. The method of claim 42, wherein handling the ejection event further includes:
requesting an operating system to eject the root controller; and
unloading a bus driver associated with the root controller.

44. The method of claim 43, wherein the pool of resources is assigned to a pooling device, wherein the pooling device is a firmware device that stores the handler code.

45. The method of claim 39, wherein the window of resources is a window selected from a group consisting of an I/O window, a memory window, and a window of bus identification numbers.
